(19) United States
(12) Patent Application Publication
(10) Pub. No.: US 2025/0089324 A1
(43) Pub. Date: Mar. 13, 2025

(54) METHODS FOR FORMING GATE OXIDE LAYER FOR HIGH-VOLTAGE TRANSISTOR

(71) Applicant: Taiwan Semiconductor Manufacturing Company LTD, Hsinchu (TW)

(72) Inventors: Jhu-Min Song, Nantou (TW); Yi-Kai Ciou, Taoyuan (TW); Chi-Te Lin, Hsinchu (TW); Yi-Huan Chen, Hsinchu (TW); Szu-Hsien Liu, Zhubei (TW); Chan-Yu Hung, Tainan (TW); Chien-Chih Chou, Taipei (TW); Fei-Yun Chen, Hsinchu (TW)

(21) Appl. No.: 18/244,040

(22) Filed: Sep. 8, 2023

(51) Int. Cl. H01L 29/40; H01L 21/28; H01L 29/423; H01L 29/66

(52) U.S. Cl. CPC H10D 64/01; H01L 21/28194; H01L 21/28211; H10D 64/027; H10D 64/516

(57) ABSTRACT

A gate oxide layer for a high voltage transistor is formed using methods that avoid thinning in the corners of the gate oxide layer. A recess is formed in a silicon substrate. The exposed surfaces of the recess are thermally oxidized to form a thermal oxide layer of the gate oxide layer. A high temperature oxide layer of the gate oxide layer is then formed within the exposed surfaces of the recess by chemical vapor deposition. The combination of the thermal oxide layer and the high temperature oxide layer results in a gate oxide layer that does not exhibit the double hump phenomenon in the drain current vs. gate voltage curve. The high temperature oxide layer may include a rim that extends out of the recess.

### BACKGROUND

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view showing a first example embodiment of a transistor suitable for high-voltage applications, in accordance with some embodiments. The transistor includes a gate oxide layer formed from two different layers and having a rim or “horn ring”.

FIG. 1B is a Y-axis cross-sectional view of the first example embodiment, through line B-B of FIG. 1A.

FIG. 1C is an X-axis cross-sectional view of the first example embodiment, through line C-C of FIG. 1A.

FIG. 2 is a flow chart illustrating a method for forming the transistor, in accordance with some embodiments. Various steps of this method are shown in FIGS. 4-17.

FIG. 3A is a plan view, and FIG. 3B is a Y-axis cross-sectional view after a processing step.

FIG. 4A is a plan view, and FIG. 4B is a Y-axis cross-sectional view after a processing step.

FIG. 5A is a plan view, FIG. 5B is a Y-axis cross-sectional view, and FIG. 5C is an X-axis cross-sectional view after a processing step.

FIG. 6A is a plan view, FIG. 6B is a Y-axis cross-sectional view, and FIG. 6C is an X-axis cross-sectional view after a processing step.

FIG. 7A is a plan view, and FIG. 7B is a Y-axis cross-sectional view after a processing step.

FIG. 8A is a plan view, and FIG. 8B is a Y-axis cross-sectional view after a processing step.

FIG. 9A is a plan view, and FIG. 9B is a Y-axis cross-sectional view after a processing step.

FIG. 10A is a plan view, and FIG. 10B is a Y-axis cross-sectional view after a processing step.

FIG. 11A is a plan view, FIG. 11B is a Y-axis cross-sectional view, and FIG. 11C is an X-axis cross-sectional view after a processing step.

FIG. 12A is a Y-axis cross-sectional view showing a second variation on the structure of the gate oxide layer.

FIG. 12B is a Y-axis cross-sectional view showing a third variation on the structure of the gate oxide layer.

FIG. 13A is a plan view, and FIG. 13B is a Y-axis cross-sectional view after a processing step.

FIG. 14 is a drain current vs. gate voltage curve for a transistor according to the present disclosure, having a gate oxide layer formed from two different layers and having a rim.

FIG. 15 is a drain current vs. gate voltage curve for a conventional transistor, which shows the double hump phenomenon.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them.

The present disclosure relates to various methods and structures which are useful in improving the performance of a high-voltage transistor. In such transistors and at very small device dimensions, the gate dielectric layer (also known as gate oxide layer) is formed in a recess to avoid an overly-thick gate oxide layer that can impact the lowermost interconnect layer (M1). This in turn can reduce the gate breakdown voltage (Vbd), which is the minimum voltage that causes an insulator to experience electrical breakdown and become electrically conductive. This can occur due to a thinner interlayer dielectric layer which occurs due to the overly-thick gate oxide layer. However, recessed gate oxide layers have a corner thinning problem which occurs because the corners cannot provide enough silicon atoms during oxidation. As a result, there is only a slight growth of oxide at the edges of the silicon surface. An undesirable side effect of this structure is a bimodal “double hump” in the drain current versus gate voltage (Id-Vg) curve when a back bias voltage (Vbs) of −0.5 volts or less is applied. This occurs because the channel device threshold voltage (Vt1) is greater than the corner device threshold voltage (Vt2). In the present disclosure, corner thinning is reduced, avoided, or prevented by use of a specified gate oxide layer structure.

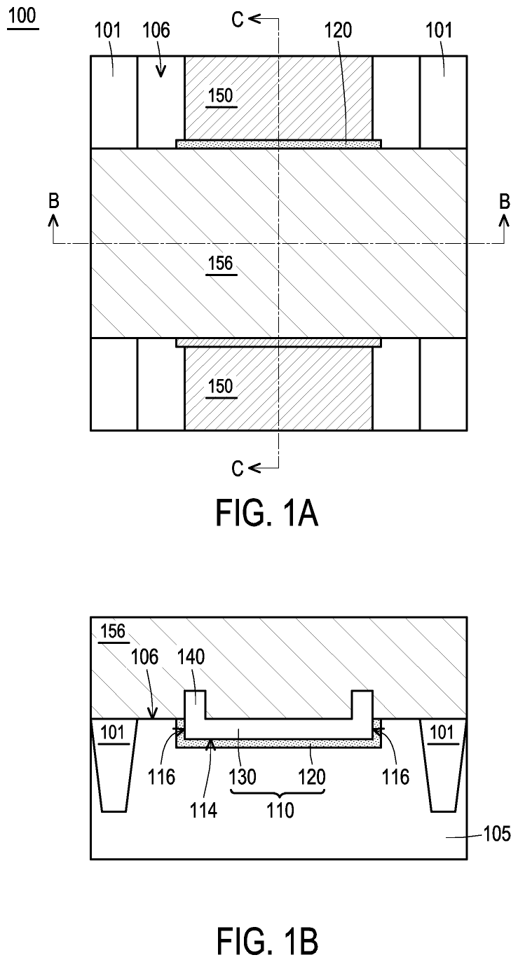

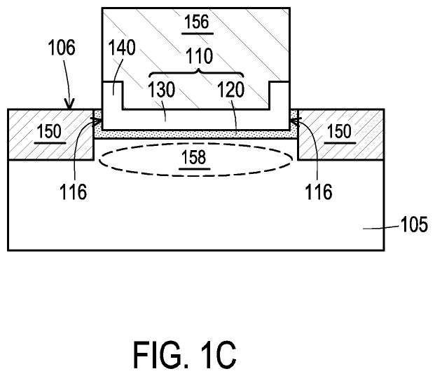

FIG. 1A is a plan view showing a first example embodiment of a high-voltage transistor, in accordance with some embodiments of the present disclosure, and illustrating some features. FIG. 1B is a Y-axis cross-sectional view of the first example embodiment, through line B-B of FIG. 1A, showing additional features. FIG. 1C is an X-axis cross-sectional view of the first example embodiment, through line C-C of FIG. 1A. Subsequent Y-axis views will also be taken along line B-B of FIG. 1A, and subsequent X-axis views will also be taken along line C-C of FIG. 1A.

Referring to all three figures together, the transistor 100 is defined between two shallow trench isolation (STI) regions 101 which are formed in a substrate 105. A gate oxide layer 110 is formed from two separate layers, a thermal oxide layer 120 and a high temperature oxide (HTO) layer 130. The gate oxide layer 110 is formed in a recess in the upper surface 106 of the transistor. As best seen in FIG. 1B and FIG. 1C, the thermal oxide layer 120 is formed entirely below the upper surface 106 of the substrate. Generally speaking, the thermal oxide layer 120 is formed on the bottom wall 114 and the sidewall(s) 116 of the recess. As illustrated here, the recess has a square shape in the plan view of FIG. 1A, and the thermal oxide layer may be considered as covering the bottom wall and the four sides of the square. The high temperature oxide layer 130 fills the remainder of the recess, and also forms a rim 140 extending out of the recess and located above the upper surface 106 of the substrate. As illustrated here, the rim can be described as being formed from four walls. In the cross-sectional views of FIG. 1B and FIG. 1C, the rim looks like a pair of horns extending upwards. The rim could also be described as a “horn ring”.

Source/drain terminals 150 are formed on opposite sides of the gate oxide layer 110. It is noted the width of the gate oxide layer 110 is greater than or equal to the width of the source/drain terminals. A gate terminal 156 is formed above the gate oxide layer 110 and running perpendicular to the source/drain terminals 150. The rim 140 of the HTO layer may be described as extending into the gate terminal 156, or the gate terminal may be described as covering the rim 140. The portion of the substrate under the gate oxide layer 110 and between the source/drain terminals 150 acts as a semiconducting channel 158 for the transistor (illustrated with dashed-line ellipse).

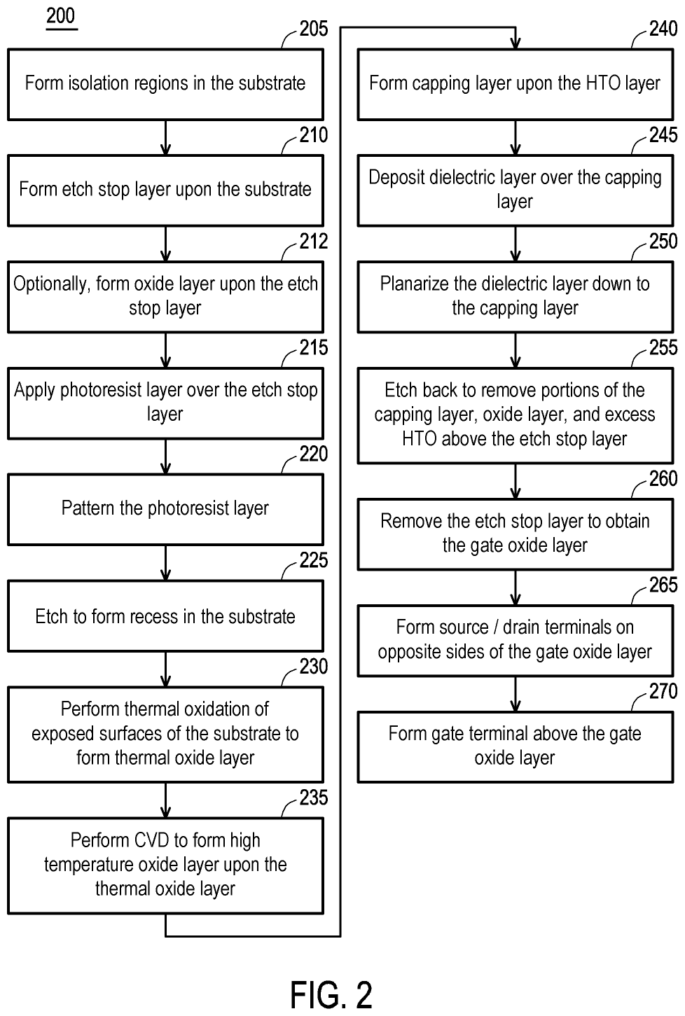

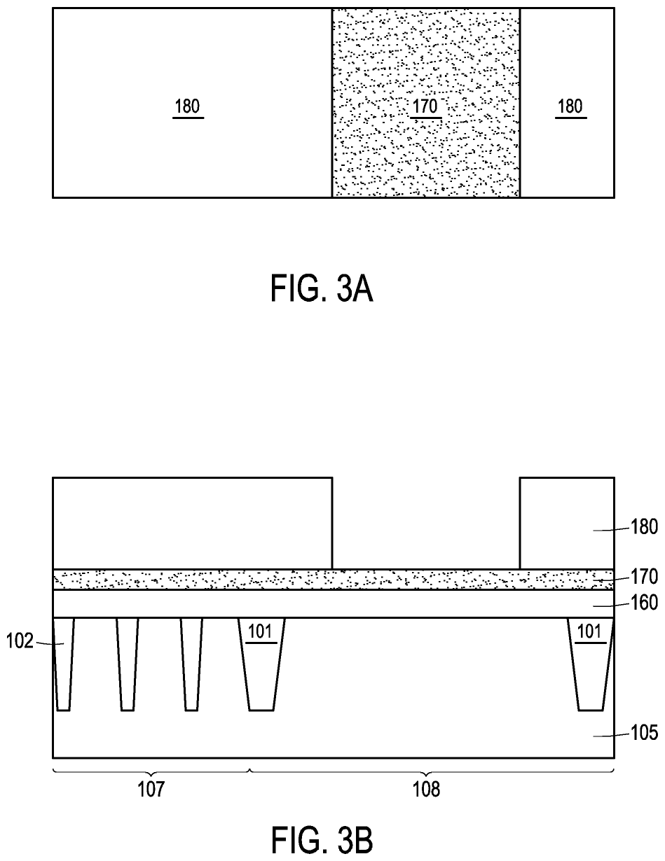

FIG. 2 is a flow chart illustrating a method 200 for making a transistor, in accordance with some embodiments. Some steps of the method are also illustrated in FIGS. 3-12. These figures provide different views for better understanding. While the method steps are discussed below in terms of forming a single transistor, such discussion should also be broadly construed as applying to the formation of multiple transistors concurrently.

It is noted that certain conventional steps are not expressly described in the discussion below. For example, the pattern/structure formed in a given layer may be done by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Continuing, then, and referring to FIG. 2 and FIGS. 3A-3C, in step 205, isolation regions 101 are formed in the substrate 105. This may be done by applying a photoresist layer (not shown) upon the substrate, patterning the photoresist layer, and etching the substrate to transfer the photoresist pattern to the substrate. The trenches formed in the substrate via such etching are then filled with a dielectric material to form isolation regions. The isolation regions may be, for example, shallow trench isolation (STI) regions or deep trench isolation (DTI) regions. The dielectric material in the STI regions is commonly a silicon oxide, although other dielectric materials can also be used such as undoped polysilicon, silicon nitride, silicon oxynitride, fluoride-doped silicate glass, or other dielectric material. The deposition can be done using physical vapor deposition (PVD) or chemical vapor deposition (CVD) or spin-on processes known in the art, or can be grown via oxidation. The patterned photoresist layer is then removed.

The substrate 105 itself is usually a wafer made of a semiconducting material. In the present disclosure, the substrate contains silicon, for example in the form of crystalline Si or polycrystalline Si. In alternative embodiments, the substrate can be made of a silicon-containing compound semiconductor such as silicon carbide (SiC), silicon germanium, or silicon germanium carbide. In particular embodiments, the wafer substrate is silicon.

In step 210 of FIG. 2, an etch stop layer 160 is then formed on the substrate. Generally, the etch stop layer is made of a different material from the substrate and the STI regions, and is usually a dielectric material. Examples of suitable dielectric materials may include silicon carbon nitride (SiCN), aluminum oxide (Al₂O₃), silicon nitride (SiN), hafnium silicates (HfSiₓO_{y}), zirconium silicates (ZrSiₓO_{y}), hafnium dioxide (HfO₂), zirconium dioxide (ZrO₂), hafnium oxynitride (HfOₓN_{y}) or zirconium oxynitride (ZrOₓN_{y}). In some specific embodiments, the dielectric material used to form the etch stop layer is silicon nitride (SiN). In particular embodiments, the etch stop layer has a thickness of about 40 angstroms to about 60 angstroms, although other values and ranges are also within the scope of this disclosure.

In optional step 212, another oxide layer 170 is formed upon the etch stop layer 160. The oxide layer 170 is formed from a different material than the etch stop layer 160. In particular embodiments, this oxide layer is applied by plasma-enhanced chemical vapor deposition (PECVD), although other processes may be used. The oxide layer may be formed from suitable oxides such as silicon dioxide (SiO₂), aluminum oxide (Al₂O₃), hafnium dioxide (HfO₂), or zirconium dioxide (ZrO₂).

Then, in step 215 of FIG. 2, a photoresist layer 180 is applied upon/over the etch stop layer 160. The photoresist layer 180 is also located over the optional oxide layer 170. In step 220, the photoresist layer 180 is patterned.

FIG. 3A and FIG. 3B show the resulting structure. FIG. 3A is a plan view, and FIG. 3B is a Y-axis cross-sectional view. Referring to FIG. 3B, a low-voltage region 107 is illustrated to the left-hand side, and a low-voltage region 108 is illustrated to the right-hand side. In the low-voltage region 107, the STI regions 102 may be thinner and closer together compared to the low-voltage region 108. The STI regions 101, 102 are shown extending along the Y-axis. STI regions extending in the X-axis are not shown here. Active regions can be considered to be defined between each pair of isolation regions along each axis.

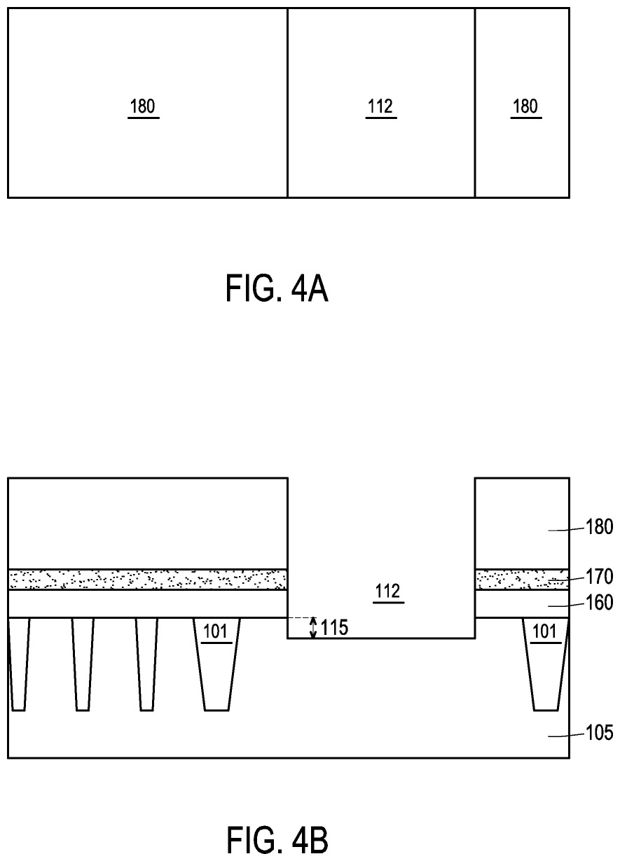

Next, in step 225 of FIG. 2, etching is performed through the oxide layer 170, the etch stop layer 160, and into the substrate 105 to form a recess 112 in the substrate. The resulting structure is shown in FIG. 4A and FIG. 4B. In particular embodiments, the recess has a depth 115 of about 200 angstroms to about 250 angstroms, although other values and ranges are also within the scope of this disclosure.

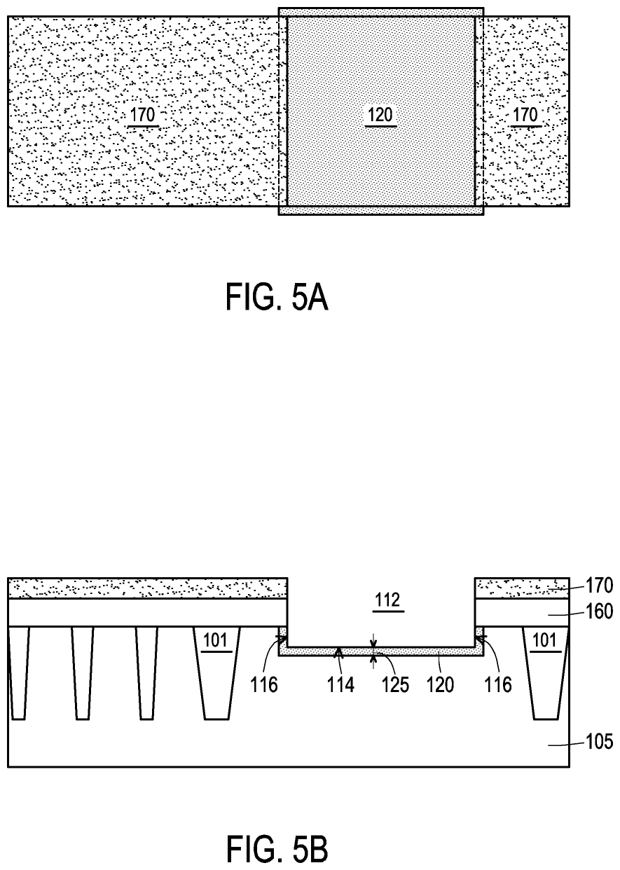

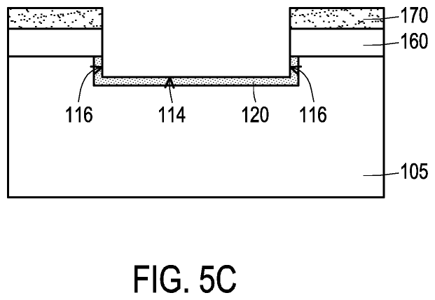

Then, in step 230 of FIG. 2 and as illustrated in FIGS. 5A-5C, thermal oxidation is performed upon the exposed surfaces of the recess 112. In particular embodiments, the thermal oxidation occurs at a temperature of about 900° C. to about 950° C., although other values and ranges are also within the scope of this disclosure. The thermal oxidation may be performed in the presence of water or oxygen (O₂) which provides oxygen atoms that react with the silicon atoms in the substrate 105. As a result, a thermal oxide layer 120 is formed on the exposed surfaces. As illustrated in FIGS. 5A-5C, the thermal oxide layer 120 is formed on the bottom wall 114 and the four sidewalls 116 of the recess. In particular embodiments, the thermal oxide layer has a thickness 125 of about 50 angstroms to about 80 angstroms, although other values and ranges are also within the scope of this disclosure. In more specific embodiments, the thermal oxide layer has a thickness 125 of about 70 angstroms. The thermal oxide layer is the first part of the overall gate oxide layer.

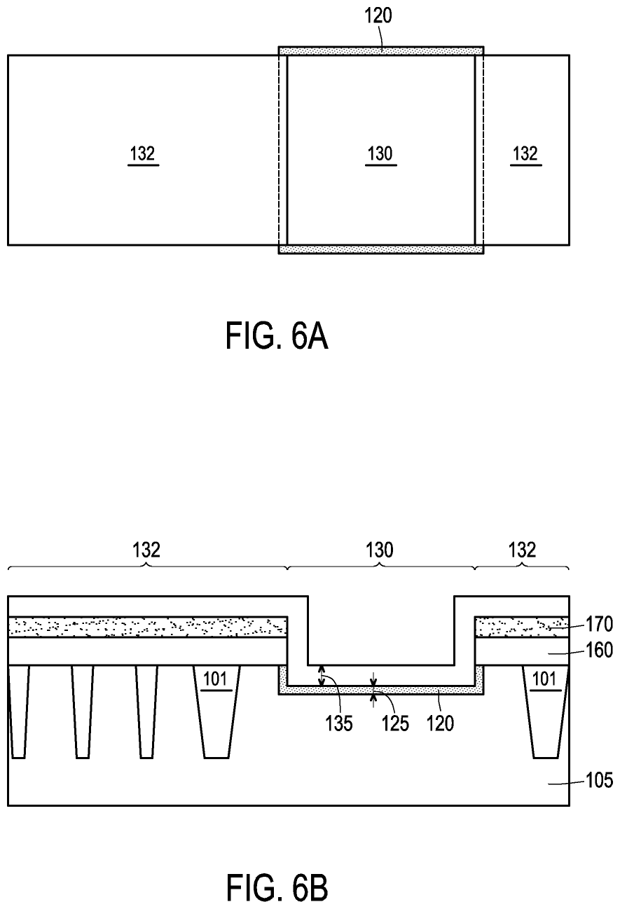

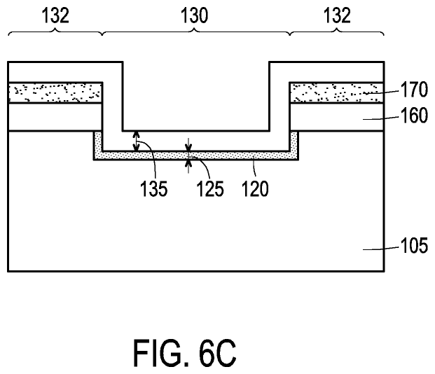

Next, in step 235 of FIG. 2 and as illustrated in FIGS. 6A-6C, chemical vapor deposition (CVD) is performed upon the substrate to form a high temperature oxide (HTO) layer 130. The HTO layer is formed upon the exposed surfaces of the thermal oxide layer 120. Excess HTO 132 is also formed over the etch stop layer 160 and the optional oxide layer 170, and can also be considered as being over the substrate. The HTO layer is the second part of the overall gate oxide layer 110. In particular embodiments, the CVD/high temperature oxidation occurs at a temperature of about 780° C. to about 800° C., although other values and ranges are also within the scope of this disclosure. The CVD is performed using a silicon-containing source gas that acts as a silicon precursor, providing silicon for the reaction. Examples of such silicon precursors include, but are not limited to, tetraethyl orthosilicate (TEOS), silane (SiH₄), trimethylsilane, tetramethylsilane, and hexachlorodisilane (HCDS). Water, oxygen (O₂), or ozone (O₃) can be used to provide oxygen atoms for the reaction. Again, the CVD may be PECVD. In particular embodiments, the resulting HTO layer has a thickness 135 of about 140 angstroms to about 170 angstroms, although other values and ranges are also within the scope of this disclosure. In more specific embodiments, the HTO layer has a thickness 135 of about 150 angstroms. After this step, the recess 112 is desirably completely filled.

In particular embodiments, the ratio of the thickness 125 of the thermal oxide layer to the thickness 135 of the high temperature oxide layer is from about 0.40 to about 0.55, although other values and ranges are also within the scope of this disclosure. The ratio of the thickness 125 of the thermal oxide layer to the thickness 135 of the high temperature oxide layer may also be written as from about 50:170 to about 80:140. These combinations permit the formation of a gate oxide layer that is sufficient to perform its function with reduced corner thinning and higher reliability.

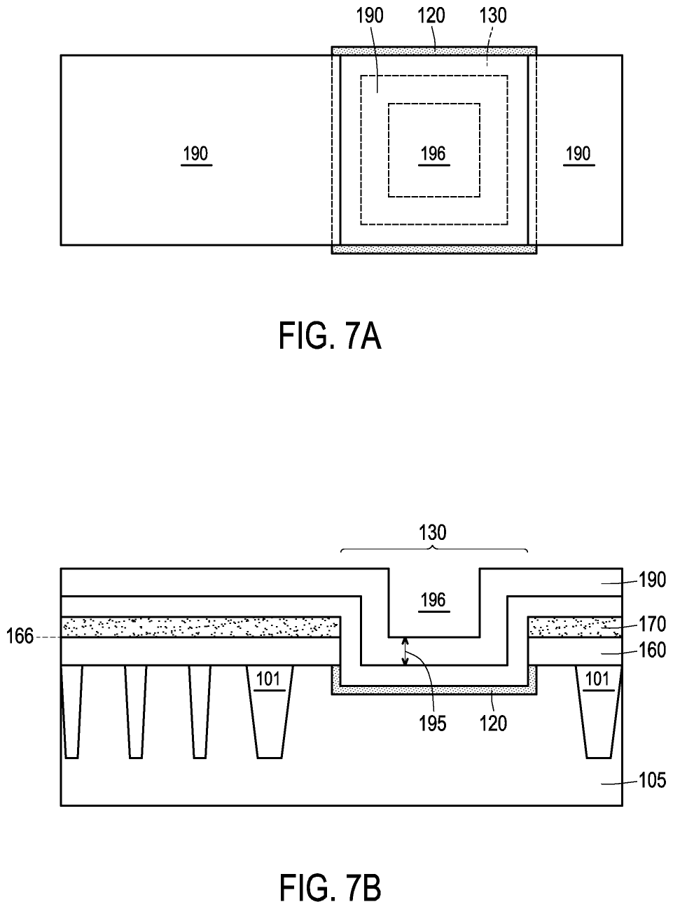

Continuing, in step 240 of FIG. 2 and as illustrated in FIG. 7A and FIG. 7B, a capping layer 190 is formed upon the HTO layer 130, and can also be considered as being over the substrate. The capping layer can be formed by physical vapor deposition (PVD), chemical vapor deposition (CVD), atomic layer deposition (ALD), or other suitable deposition technique or growth technique. The capping layer is made from the same material as the etch stop layer 160 (the reason for which will be discussed further below). In particular embodiments, the capping layer is formed from silicon nitride (SIN). The capping layer conforms to the surface of the HTO layer. Desirably, the thickness 195 of the capping layer 190 is sufficient so that the height of the capping layer 190 within the recess matches the height of the etch stop layer 160, which is indicated with reference number 166. The dotted lines in FIG. 7A indicate the locations of the thermal oxide layer 120, the HTO layer 130, the capping layer 190, and “empty” space 196 above the recess.

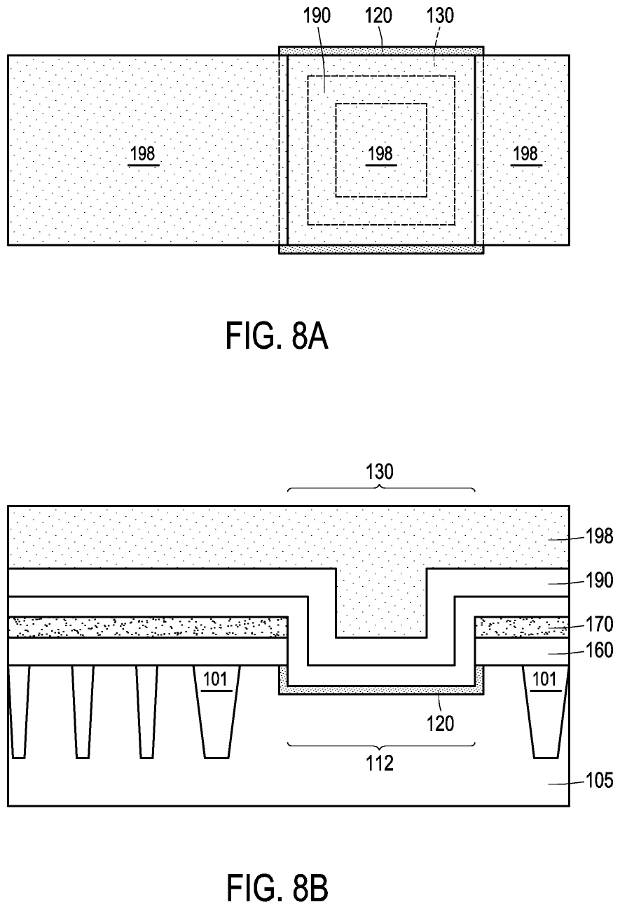

Then, in step 245 of FIG. 2 and as illustrated in FIG. 8A and FIG. 8B, a dielectric layer 198 is deposited upon the capping layer 190, to fill any remaining gaps above the recess 112. The dielectric layer may be made of any suitable dielectric material, several of which have already been described herein. Any suitable process may be used. In particular embodiments, flowable CVD is used to form the dielectric layer 198. Very generally, in flowable CVD, a liquid mixture containing a silicon precursor is deposited upon the substrate and flow to fill in any gaps, such as those remaining over the recess 112. Energy is then applied (for example, thermal or plasma) to remove the liquid and cause hydrolysis of the silicon precursor and formation of the dielectric layer. Annealing may also be performed to harden the dielectric layer. The dotted lines in FIG. 8A indicate the locations of the thermal oxide layer 120, the HTO layer 130, the capping layer 190, and dielectric layer 198 within the recess.

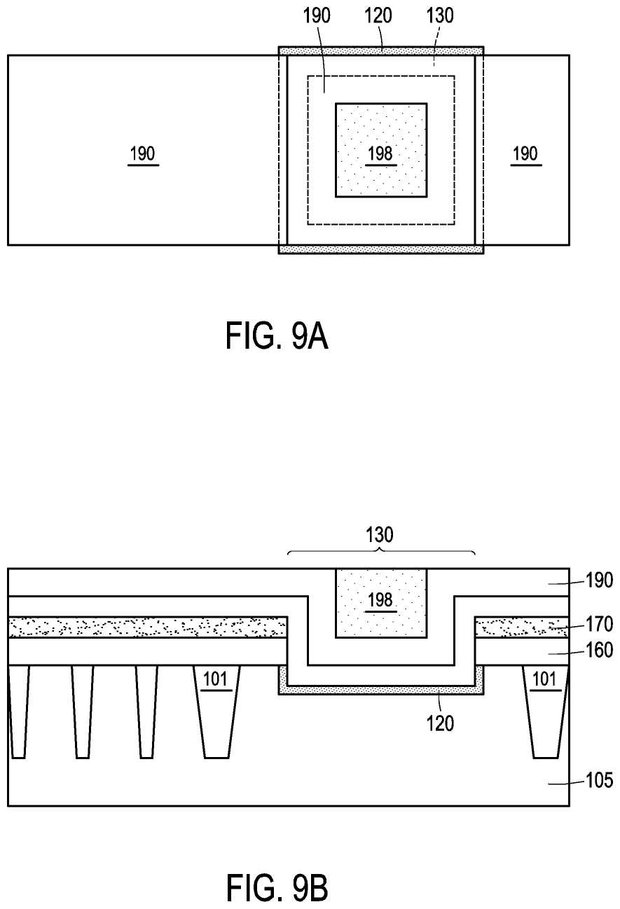

Then, in step 250 of FIG. 2 and as illustrated in FIG. 9A and FIG. 9B, the dielectric layer 198 is planarized down to the capping layer 190. The planarizing may be performed, for example, using a chemical mechanical polishing (CMP) process.

Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate, removing undesired materials and creating a highly level surface on the wafer. A post-CMP cleaning step is then carried out using rotating scrubber brushes along with a washing fluid to clean one or both sides of the wafer substrate.

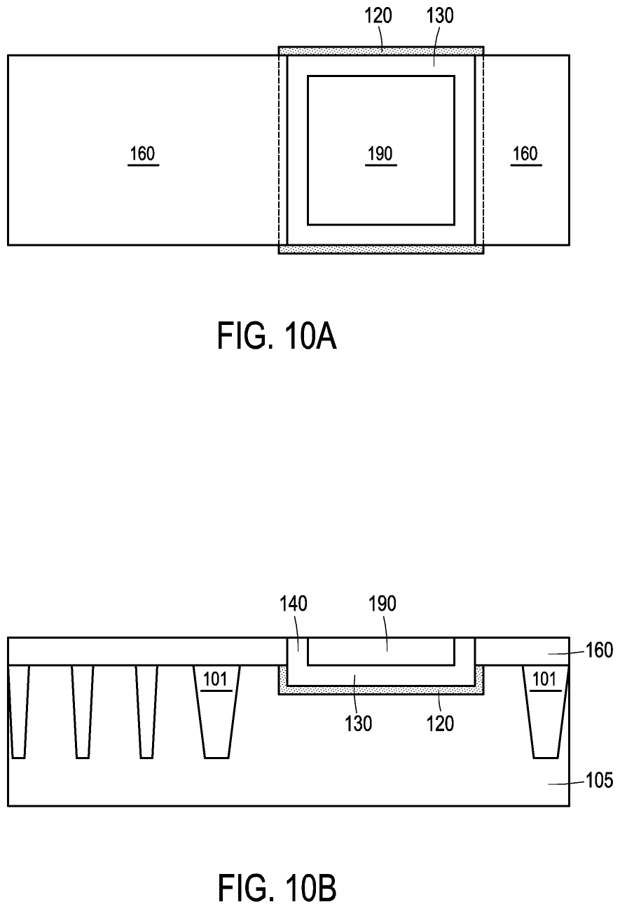

Subsequently, in step 255 of FIG. 2 and as illustrated in FIG. 10A and FIG. 10B, etching back is performed to remove the portions of the capping layer 190, the optional oxide layer 170, and the excess HTO 132 which are located above the etch stop layer 160. It is noted that the portion of the capping layer 190 located above the recess 112 is not etched back, and could also be described as now forming a portion of the etch stop layer 160. As a result of this step, the rim 140 of the HTO layer 130 of the gate oxide layer is formed.

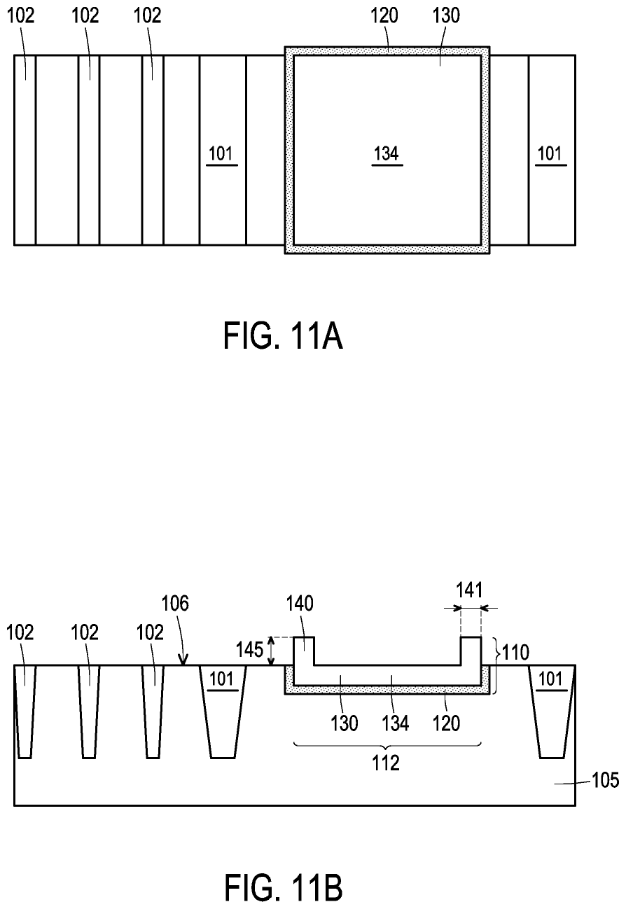

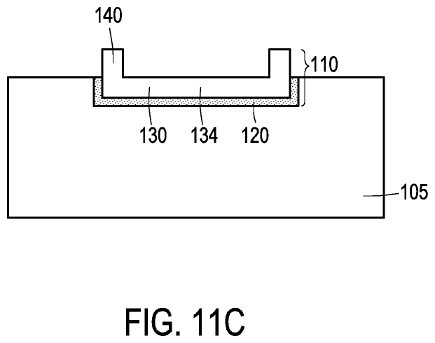

Finally, in step 260 of FIG. 2 and as illustrated in FIGS. 11A-11C, the etch stop layer 160 is removed, including the portion of the capping layer 190 located within the rim. Thus, the gate oxide layer 110 is obtained within the recess. The gate oxide layer 110 is formed from the combination of the thermal oxide layer 120 and the HTO layer 130. The thermal oxide layer 120 is present on all surfaces of the recess, and the HTO layer 130 is present upon the surfaces of the thermal oxide layer 120. The rim 140 of the HTO layer 130 extends upwards and out of the recess 112, while the bottom portion 134 of the HTO layer 130 is present within the recess.

In particular embodiments, the rim 140 has a height or thickness 145 of about 40 angstroms to about 60 angstroms, although other values and ranges are also within the scope of this disclosure. The height or thickness of the rim is measured above the upper surface 106 of the substrate. In particular embodiments, the rim 140 has a width 141 of about 140 angstroms to about 170 angstroms, although other values and ranges are also within the scope of this disclosure.

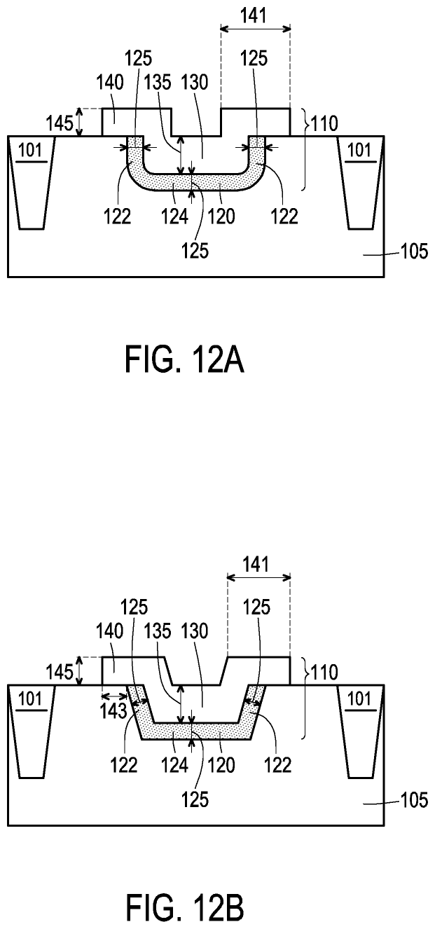

FIG. 12A and FIG. 12B are Y-axis cross-sectional views of different embodiments that illustrate some variations in the structure of the gate oxide layer 110.

First, comparing FIG. 12A to FIG. 11B, the corners of the thermal oxide layer 120 of FIG. 12A are more rounded, creating a U-shaped cross-section. In contrast, the corners of the thermal oxide layer 120 of FIG. 11B are closer to 90°. The shape of the corners may vary depending on the process used to form the recess in the substrate (see step 225).

In addition, the rim 140 of FIG. 12A extends horizontally on top of the substrate and covers the sides 122 of the thermal oxide layer 120, not just the bottom 124 of the thermal oxide layer 120. In contrast, in FIG. 11B the rim 140 does not cover the sides of the thermal oxide layer 120. This aspect may depend, in part, on the accuracy and resolution with which the etch stop layer 160, the photoresist layer 180, and subsequent etching of the recess (see steps 210, 215, 220, 225) are performed, which may be intentional or inadvertent. The other dimensions of the layers are as previously described.

In the second variation illustrated in FIG. 12B, the thermal oxide layer 120 has a V-shaped cross-section. Again, this shape will depend on the process used to form the recess in the substrate. In addition, the rim 140 of FIG. 12B also extends horizontally on top of the substrate and covers the sides 122 of the thermal oxide layer 120, and also extends beyond the thermal oxide layer 120. Here, the width of the portion of the rim extending beyond the thermal oxide layer is indicated with reference number 143. In particular embodiments, the width 143 extending beyond the thermal oxide layer is from about 20 angstroms to about 50 angstroms, although other values and ranges are also within the scope of this disclosure. The other dimensions of the layers are as previously described.

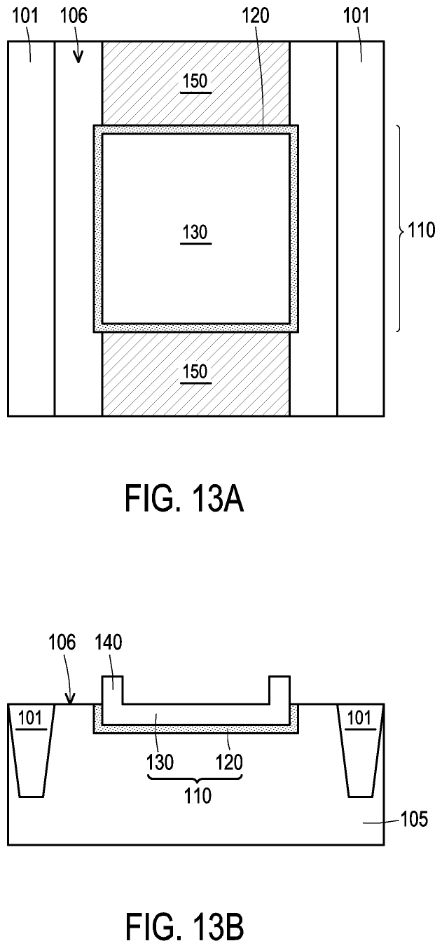

Referring back to FIG. 2, at this point the gate oxide layer 110 has been formed. Now, the rest of the transistor is formed. Continuing, in step 265 of FIG. 2 and as illustrated in FIG. 13A and FIG. 13B, source/drain terminals 150 are formed on opposite sides of the gate oxide layer 110. In particular embodiments, these terminals are formed via ion implantation. Briefly, an ion implanter is used to implant atoms into a silicon crystal lattice, modifying the conductivity of the lattice in the implanted location. An ion implanter generally includes an ion source, a beam line, and a process chamber. The ion source produces the desired ions (here, for example, Co, Ti, Ni, Pt, or Pb). The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of a metal, following by annealing in which the metal reacts with the underlying exposed silicon. Unreacted metal can then be removed, for example with a selective etch process.

Finally, in step 270 of FIG. 2, a gate terminal is formed above the gate oxide layer. The gate material may be any suitable material, for example polysilicon or an electrically conductive metal or other electrically conductive material. This layer may be formed using suitable processes such as CVD, PVD, or ALD, or other deposition techniques. The resulting structure is the high-voltage transistor shown in FIGS. 1A-1C. Again, it is noted that the gate terminal 156 covers the rim 140 of the gate oxide layer 110. The gate terminal 156 does not contact the source/drain terminals 150.

Additional processing steps may be performed to obtain devices with integrated circuits (ICs) containing the high-voltage transistor. These ICs can be used in various applications such as BCD (Bipolar-CMOS-DMOS) circuits for driving discrete high voltage components; driver ICs which may have high voltage, medium voltage, and low voltage components integrated together onto the same chip that can be used in LCD, OLED, AMOLED, or QLED display panels; image sensors that can be used in systems such as mobile telephones, facial recognition systems, or as motion sensors for automotive applications, security applications, energy efficiency, etc.; power management ICs that control the flow and direction of electrical power; and/or image signal processors (ISP).

Other components that may be included on the chip of a driver IC may include high voltage components such as a gate driver and a step-up circuit; medium voltage components like a source driver and a liquid crystal (LC) driver; and low voltage components such as a memory buffer, a timing generator, a gamma adjuster, and/or a CPU interface. A gate driver controls the transistors within each pixel in a row of the display panel. The source driver generates voltages that are applied to the liquid crystal within each pixel (column) on that row for data input. The combination determines the grayscale and color generated by each pixel. The timing generator analyzes the signal from the CPU, converts it to a signal that the gate drivers and source drivers understand, and controls the timing for when the various components send their signals to the display panel, so that the desired image is generated. The step-up circuit increases the input voltage to a higher output voltage and regulates the output voltage so that it remains constant. The LC driver controls the orientation of the liquid crystal layer within the pixel, which determines whether light passes through the pixel or not, and aids in contrast. The memory buffer is used to store the data that determines what is and will be shown on the display panel, and is used to drive the gate drivers and source driver. The gamma adjuster changes the applied voltage to each pixel to obtain the desired luminance and optimize image quality. The CPU interface permits the drive IC to communicate with the microcontroller/computer.

An image sensor is typically made up of several cells, and each cell includes a photodetector (such as a photodiode) and one or more transistors. The transistor can be used as an amplifier or switch.

A power management IC can include circuits for DC to DC conversion, changing voltages from an input voltage to a different output voltage (higher or lower), and/or voltage regulation. A clock may also be present.

An image signal processor can include an analog-to-digital (A/D) converter, a digital signal processor, and a memory unit, any of which may include a high-voltage transistor as described herein. The digital signal processor may be used for color correction, noise reduction, white balance, and/or gamma correction.

The gate oxide layers of the present disclosure have a combination of advantages. The gate oxide layer does not exhibit the double hump phenomenon in the drain current vs. gate voltage curve. This is because the corner thinning problem that occurs with an overly thick thermal oxide layer is avoided by use of the HTO layer. At the same time, the reduced oxide quality of the HTO layer is increased by the presence of the high oxide quality layer formed by thermal oxidation. Concurrently, the gate oxide layer has high overall integrity/quality, with a breakdown voltage of at least 8 volts.

Some aspects of the present disclosure thus relate to methods for forming a gate oxide layer of a high voltage transistor. A recess is formed in a substrate. Exposed surfaces of the recess are then thermally oxidized to form a thermal oxide layer of the gate oxide layer; Chemical vapor deposition is then performed upon the thermal oxide layer to form a high temperature oxide layer of the gate oxide layer.

Also disclosed herein in various embodiments are methods for forming a high voltage transistor. An etch stop layer is formed on a substrate. A photoresist layer is applied upon the etch stop layer, and then patterned. Next, etching is performed through the etch stop layer and into the substrate to form a recess in the substrate. Exposed surfaces of the recess are then thermally oxidized to form a thermal oxide layer of the gate oxide layer; Chemical vapor deposition is then performed upon the thermal oxide layer to form a high temperature oxide layer of the gate oxide layer upon the exposed surfaces of the thermal oxide layer. Excess high temperature oxide is usually also formed upon the etch stop layer. A capping layer is formed upon the high temperature oxide layer. A dielectric layer is deposited upon the capping layer. The dielectric layer is then planarized. Next, etch back is performed to remove the capping layer and the excess high temperature oxide layer upon the etch stop layer. The etch stop layer is then removed to obtain the gate oxide layer within the recess. The gate oxide layer comprises the thermal oxide layer and the high temperature oxide layer. Source/drain terminals are then formed in the substrate on opposite sides of the gate oxide layer. A gate terminal is then formed above the gate oxide layer.

Also disclosed herein in various embodiments are transistors for high-voltages applications. The transistor comprises a substrate that has a recess therein. The recess includes a gate oxide layer comprising a thermal oxide layer on all surfaces of the recess and a high temperature oxide layer upon the surfaces of the thermal oxide layer. Source/drain terminals are located on opposite sides of the gate oxide layer. A gate terminal is located over the gate oxide layer. The high temperature oxide layer forms a rim extending out of the recess and into the gate terminal.

Also disclosed herein are integrated circuits (ICs) containing the high-voltage transistor, and devices including such ICs. The ICs may include BCD circuits; driver ICs; or power management ICs. Devices may include image sensors and/or image signal processors (ISP).

The methods and devices of the present disclosure are further illustrated in the following non-limiting working examples, it being understood that the examples are intended to be illustrative only and that the disclosure is not intended to be limited to the materials, conditions, process parameters and the like recited herein.

### EXAMPLES

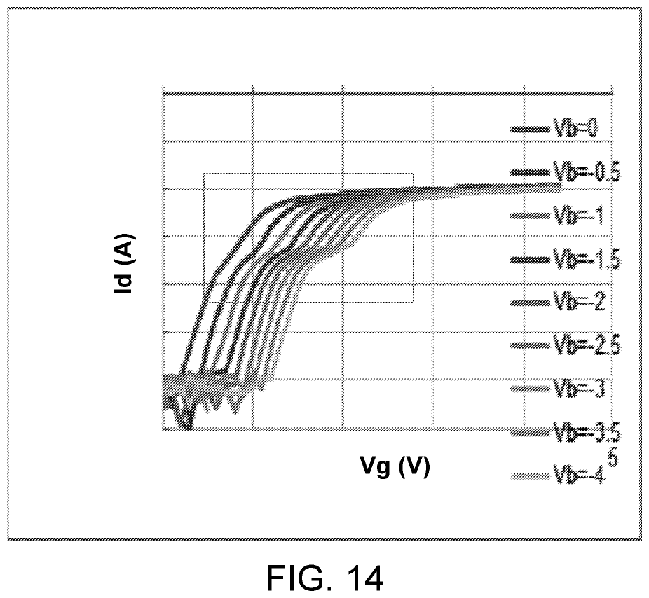

Transistors were made with a gate oxide layer comprising a thermal oxide layer and a high temperature oxide layer as described in the present disclosure, and the Id-Vg curve was measured at offset bias voltages (Vb) of 0 to 4 volts at intervals of 0.5 volts. The resulting curves are shown in FIG. 14. There is no double hump effect in these curves.

For comparative purposes, the same measurements were made on transistors made with a gate oxide layer of the same thickness, but made only via thermal oxidation.

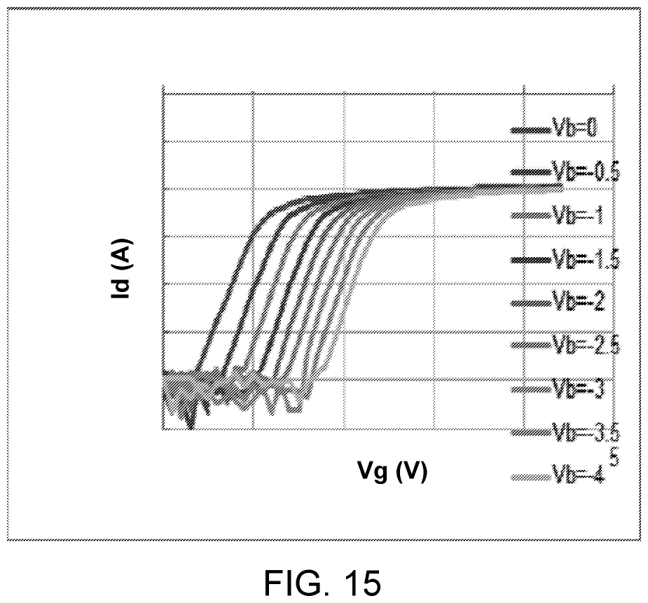

The resulting curves are shown in FIG. 15. The double hump effect is highlighted in the square.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a gate oxide layer of a high voltage transistor, comprising:
forming a recess in a substrate;
thermally oxidizing exposed surfaces of the recess to form a thermal oxide layer of the gate oxide layer;
performing chemical vapor deposition upon the thermal oxide layer to form a high temperature oxide layer of the gate oxide layer.

2. The method of claim 1, wherein the thermal oxidation occurs at a temperature of about 900°° C. to about 950° C.

3. The method of claim 1, wherein the chemical vapor deposition occurs at a temperature of about 780°° C. to about 800° C.

4. The method of claim 1, wherein the chemical vapor deposition uses a silicon precursor.

5. The method of claim 1, wherein the thermal oxide layer has a thickness of about 50 angstroms to about 80 angstroms.

6. The method of claim 1, wherein the high temperature oxide layer has a thickness of about 140 angstroms to about 170 angstroms.

7. The method of claim 1, wherein the gate oxide layer has a thickness of about 200 angstroms to about 250 angstroms.

8. The method of claim 1, wherein a ratio of a thickness of the thermal oxide layer to a thickness of the high temperature oxide layer is from about 0.40 to about 0.55.

9. The method of claim 1, wherein the gate oxide layer has a breakdown vbreoltage of at least 8 volts.

10. The method of claim 1, wherein the high temperature oxide layer forms a rim extending out of the recess.

11. The method of claim 10, wherein the rim has a height of about 40 angstroms to about 60 angstroms.

12. The method of claim 10, wherein the rim has a width of about 140 angstroms to about 170 angstroms.

13. The method of claim 1, wherein the rim extends horizontally beyond the thermal oxide layer by a width of about 20 angstroms to about 50 angstroms.

14. A method for forming a high voltage transistor, comprising:
forming an etch stop layer on a substrate;
applying a photoresist layer upon the etch stop layer;
patterning the photoresist layer;
etching through the etch stop layer and into the substrate to form a recess in the substrate;
thermally oxidizing exposed surfaces of the recess to form a thermal oxide layer of the gate oxide layer;
performing chemical vapor deposition to form a high temperature oxide layer of the gate oxide layer upon the exposed surfaces of the thermal oxide layer and excess high temperature oxide upon the etch stop layer;
forming a capping layer upon the high temperature oxide layer;
depositing a dielectric layer upon the capping layer;
planarizing the dielectric layer;
etching back to remove the capping layer and the excess high temperature oxide layer upon the etch stop layer;
removing the etch stop layer to obtain the gate oxide layer within the recess, the gate oxide layer comprising the thermal oxide layer and the high temperature oxide layer;
forming source/drain terminals in the substrate on opposite sides of the gate oxide layer; and
forming a gate terminal above the gate oxide layer.

15. The method of claim 14, wherein the etch stop layer is formed from a nitride.

16. The method of claim 14, wherein the etch stop layer has a thickness of about 40 angstroms to about 60 angstroms.

17. The method of claim 14, further comprising forming an oxide layer over the etch stop layer prior to applying the photoresist layer.

18. A high voltage transistor, comprising:
a substrate having a recess therein, the recess including a gate oxide layer comprising a thermal oxide layer on all surfaces of the recess and a high temperature oxide layer upon the surfaces of the thermal oxide layer;
source/drain terminals on opposite sides of the gate oxide layer; and
a gate terminal over the gate oxide layer;
wherein the high temperature oxide layer forms a rim extending out of the recess and into the gate terminal.

19. The transistor of claim 18, wherein a ratio of a thickness of the thermal oxide layer to a thickness of the high temperature oxide layer is from about 0.40 to about 0.55.

20. The transistor of claim 18, wherein the rim has a height of about 40 angstroms to about 60 angstroms.
